(19) United States
(12) Patent Application Publication
(10) Pub. No.: US 2023/0208414 A1
(43) Pub. Date: Jun. 29, 2023

(54) VARACTOR INTEGRATION-BASED VOLTAGE COMPARATORS

(71) Applicant: CREDO TECHNOLOGY GROUP LTD, GRAND CAYMAN (KY)

(72) Inventor: YIDA DUAN, FREMONT, CA (US)

(73) Assignee: CREDO TECHNOLOGY GROUP LTD, GRAND CAYMAN (KY)

(21) Appl. No.: 17/646,233

(22) Filed: Dec. 28, 2021

(51) Int. Cl. H03K 5/24

(52) U.S. Cl. CPC H03K 5/2481

(57) ABSTRACT

Varactors may be employed to enable enhanced performance and/or reduced power consumption of integration-based voltage comparators. One illustrative voltage comparator includes: a latch having two sense transistors to set a latch to either of two complementary states; two varactors each coupled to enable one of the two sense transistors upon reaching a turn on voltage; and a differential amplifier to charge or discharge the two varactors at a differential rate proportional to a difference in input voltages. An illustrative voltage comparison method includes: converting two input voltages into two respective currents; applying each of the two respective currents to one of two respective varactors; and deriving a latch state from the varactor voltages, the latch state indicating which of the two input voltages is greater.

### BACKGROUND

Demand continues for ever-increasing volumes and rates of data communication - demand that is gradually being addressed by sophisticated techniques for transmitting and receiving ever-higher frequency and higher-bandwidth signals via various forms of wireless and physical media. Digital communications receivers increasingly require faster and more efficient components to cope with the ever-higher sample rates.

One of the more critical components of a high-speed digital communications receiver is the comparator. More precisely, digital data receivers employ one or more clocked voltage comparators at the point where the data stream is converted from analog to digital form. The clocked latch of such comparators is typically preceded by an integrator-based dynamic pre-amplifier to improve accuracy. At the cost of increased power consumption, the capacitance that provides the pre-amplifier’s integration operation may be sized up to prevent the pre-amplifier’s thermal and flicker noise from dominating the comparator’s input-referred noise. Unfortunately, power consumption limits may prevent the capacitance from being sized large enough to provide sufficient performance.

### SUMMARY

Accordingly, there are disclosed herein integration-based voltage comparators and methods employing varactors to enable enhanced performance and/or reduced power consumption. One illustrative voltage comparator includes: a latch having two sense transistors to set a latch to either of two complementary states; two varactors each coupled to enable one of the two sense transistors upon reaching a turn on voltage; and a differential amplifier to charge or discharge the two varactors at a differential rate proportional to a difference in input voltages.

Another illustrative voltage comparator includes an amplifier that provides a current based a difference between two input voltages; at least one varactor charged or discharged by the current; and at least one pair of cross-coupled transistors that derive a latch state based at least in part on a voltage of the at least one varactor.

An illustrative voltage comparison method includes: converting a difference between two input voltages into a current; applying the current to a varactor; and deriving a latch state based at least in part on a voltage of the varactor, the latch state indicating which of the two input voltages is greater. Alternatively, the method includes: converting two input voltages into two respective currents; applying each of the two respective currents to one of two respective varactors; and deriving a latch state from the varactor voltages, the latch state indicating which of the two input voltages is greater.

Each of the foregoing may be implemented individually or in combination, and may be implemented with any one or more of the following features in any suitable combination:1. pre-charge transistors to charge the two varactors before each voltage comparison. 2. for each voltage comparison, the varactors provide a capacitance that decreases as the differential amplifier discharges them. 3. pre-charge transistors to discharge the two varactors before each voltage comparison. 4. for each voltage comparison, the varactors provide a capacitance that decreases as the differential amplifier charges them. 5. reset transistors to reset the latch before each voltage comparison. 6. a clock-controlled transistor to charge the at least one varactor to a predetermined voltage before each voltage comparison. 7. clock-controlled reset transistors to place the at least one pair of cross-coupled transistors into an unlatched state before each voltage comparison. 8. a clock-controlled transistor to discharge the at least one varactor before each voltage comparison.

### BRIEF DESCRIPTION OF THE DRAWINGS

FIG. 1 is a perspective view of an illustrative fiberoptic cable connector.

FIG. 2 is a block diagram of an illustrative fiberoptic cable connector.

FIG. 3 is a block diagram of an illustrative serializer-deserializer transceiver device.

FIG. 4 is a block diagram of an illustrative data recovery and remodulation channel.

FIG. 5 is a schematic of an illustrative digital receiver.

FIG. 6 is a schematic of a first illustrative clocked voltage comparator.

FIG. 7 is a schematic of a second illustrative clocked voltage comparator.

FIGS. 8A and 8B are graphs illustrating operation of the first and second clocked voltage comparators, respectively.

### DETAILED DESCRIPTION

While specific embodiments are given in the drawings and the following description, keep in mind that they do not limit the disclosure. On the contrary, they provide the foundation for one of ordinary skill to discern the alternative forms, equivalents, and modifications that are encompassed in the scope of the appended claims.

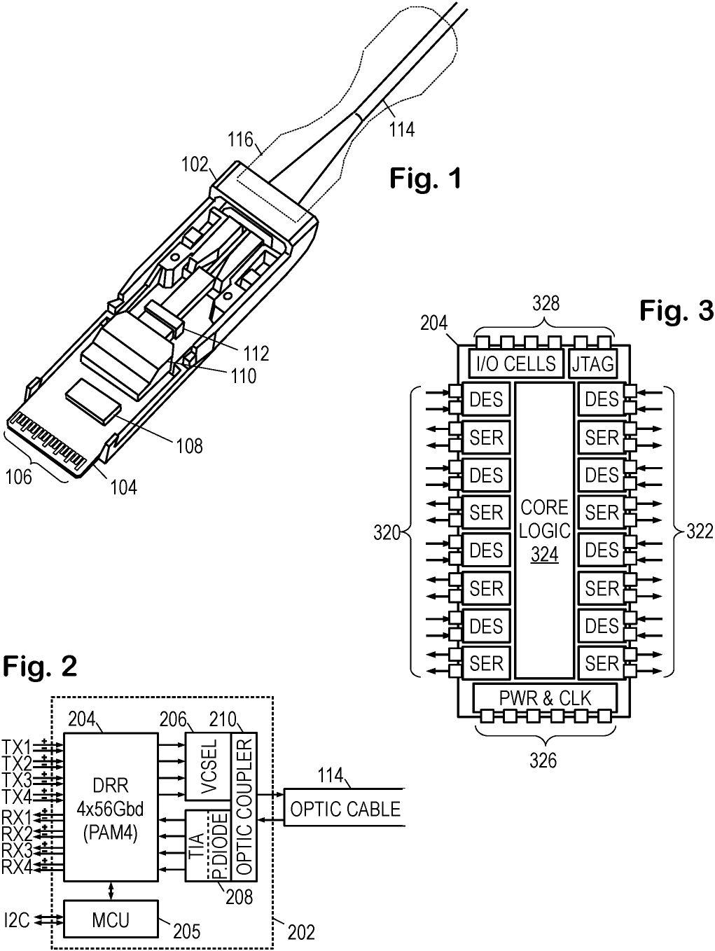

As an illustrative usage context, FIG. 1 shows a fiberoptic cable connector such as might be used to connect computers and network devices in a data processing center. A connector frame 102 houses a printed circuit board (PCB) assembly 104 configured with edge connector contacts 106. Edge connector contacts 106 mate with contacts in a socket of a host device’s network interface port to send and receive electrical signals. The PCB assembly 104 includes one or more packaged integrated circuit (IC) chips or discrete electrical components mounted to contact pads on the PCB. For example, the PCB assembly 104 may include a digital data recovery and remodulation (DRR) device 108 that equalizes received signals, recovers the data, and retransmits the recovered data, optionally with error correction, signal format conversion, and lane realignment.

The PCB assembly 104 includes an optical coupling module 110 that couples integrated photodetectors and photoemitters to one or more optical paths. When mated with the optical coupling module 110, a ferrule 112 aligns one or more optical fibers the fiberoptic cable 114 with the one or more optical paths. The optical coupling module 110 would typically use lenses and prisms to define the optical paths that couple light signals between the optical fibers and the photodetectors and photoemitters, though other optical elements (e.g., mirrors, gratings) would also be suitable.

The fiberoptic cable connector may further include a finger grip 116 and a cover to protect the other components from damage during normal use.

FIG. 2 is a block diagram to more clearly illustrate the signal flows of an illustrative fiberoptic cable connector 202. A DRR device 204 couples to the network interface port to accept, for example, 28 or 56 gigabaud (GBd) electrical transmit signals from the host on each of, say, four lanes and to accordingly provide the host with 28 or 56 GBd electrical receive signals on each of four lanes. The electrical transmit and receive signals are differential signals that may employ non-return to zero (NRZ) signaling or 4-level pulse amplitude modulation (PAM4) signaling. After accounting for overhead, the illustrative four signal lanes would collectively transport data at a nominal 100 or 200 gigabits per second (Gbps) for NRZ and 200 or 400 Gbps for PAM4.

The connector 202 may further include a microcontroller unit (MCU) 205 that couples to the network interface port via a management data bus such as the inter-integrated circuit (I2C) bus or the management data input/output (MDIO) bus. The host may use the management data bus to identify the cable’s capabilities, determine connection status, diagnose faults, and/or configure operation of the cable connector. The MCU 205 processes commands received via the management data bus to appropriately read or set the control and status registers of the DRR device 204. In at least some cases, the MCU 205 is integrated together with the DRR device 204 into a single integrated circuit substrate or package.

Optical coupling module 110 (FIG. 1) includes photoemitter array 206, optical path coupler 210, and photodetector array 208. DRR device 204 converts the electrical transmit signals into remodulated electrical transmit signals that drive an array of photoemitters 206. As one example, the photoemitters in the array are vertical cavity surface-emitting lasers (VCSEL). The electrical drive signals cause current flow in the photoemitters, which in turn emit light signals having an intensity corresponding to the amplitude of the current flow.

An optical path coupler 210 optically couples the light signals from the photoemitters to optical fibers in cable 114 and couples light signals from optical fibers cable 114 to an array of photodetectors 208. Various suitable photodetector implementations are available in the literature. As one example, the photodetectors in the array are reverse-biased photodiodes that each produce a photocurrent signal corresponding to the intensity of a received light signal. A transimpedance amplifier (TIA) converts the photocurrent signal into a voltage signal, amplifying the signal while isolating the photodiode from output voltage variation. In this fashion, the modulated optical signal intensity is converted into a modulated voltage signal for the DRR device to equalize and demodulate into a digital data stream.

DRR device 204 is preferably implemented on a monolithic integrated circuit chip. FIG. 3 is a block diagram for such a device, with contacts 320 for host-facing serializer-deserializer (SerDes) modules to receive and transmit high-rate serial bitstreams across four differential signal lanes of a bus interface, additional contacts 322 for channel-facing SerDes modules to convey the high-rate serial bitstreams to and from the transducers coupled to the fiberoptic channel, and core logic 324 for implementing a channel communications protocol while buffering bitstreams between the channel and host interface. Also included are various supporting modules and contacts 326, 328, such as power regulation and distribution, clock generation, digital input/output lines for control signals, and a JTAG module for built-in self testing.

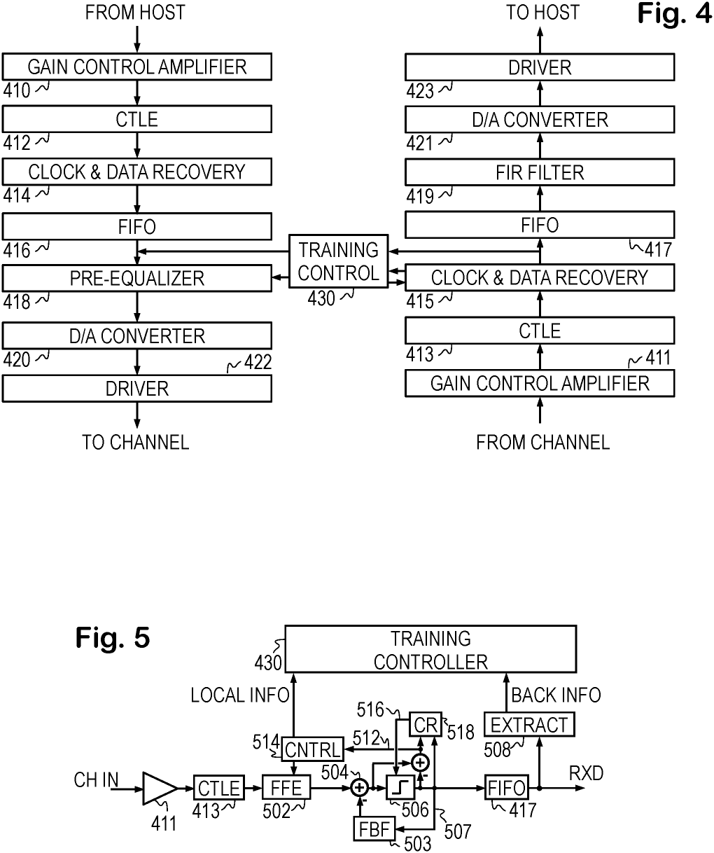

FIG. 4 is a block diagram showing illustrative operations performed by the SerDes modules for a given channel. Gain control amplifiers 410, 411 apply an adjustable gain to optimize the ranges of the receive signals from the host and channel, respectively, for processing by the subsequent components of the receive chain. Continuous time linear equalizer (CTLE) filters 412, 413 provides spectral shaping to limit bandwidth and partially compensate for channel effects. Clock and data recovery (CDR) modules 414, 415 derive a sampling clock signal from the filtered receive signals and use it to recover the corresponding symbol streams. Optional first-in first-out (FIFO) buffers 416, 417 provide buffering of the receive symbol streams from the host and channel, respectively.

The digital symbol streams leaving buffers 416, 417 are filtered by pre-equalizer 418 and FIR filter 419, respectively, to compensate for attenuation by the channel and the short reach link to the host. Digital to analog converters 420, 421 convert the filtered signals to analog form and drivers 422, 423 supply sufficient current to convey the outgoing signals across the channel and short reach link, respectively.

FIG. 4 further shows a training control module 430 to adapt local and remote filter coefficients of the CDR module 415 and pre-equalizer 418. The training control module 430 may generate a sequence of training frames that take the place of the transmit data stream for the duration of a link speed negotiation phase and a link speed training phase, and may detect equalization errors associated with training frame symbols in the receive data stream. Combining the equalization errors with the training frame symbols, the training controller 430 can adapt the coefficients of a remote pre-equalizer 418 and local CDR module 415 to optimize their combined compensation of the receive channel effects. Training controller 430 can communicate the remote pre-equalizer coefficient updates via various backchannel options including, e.g., dedicated fields in the training frames of the transmit symbol stream. Correspondingly, training controller 430 can extract updates for the local pre-equalizer 418 from dedicated fields in the frames of the receive symbol stream. For further details of one illustrative example, see, e.g., co-owned US Pat. 10,212,260 “SerDes Architecture with a Hidden Backchannel Protocol”, which is hereby incorporated herein by reference.

FIG. 5 provides additional detail regarding an illustrative implementation of CDR module 415 and training control module 430. In FIG. 5, an analog electrical signal (CH_IN) from, e.g., the TIA of a photodetector 208 is amplified by gain controller 411 and filtered by CTLE 413. Optionally, an adaptive feed-forward equalization (FFE) filter 502 may be used to reduce intersymbol interference in the filtered receive signal. An optional feedback filter (FBF) 503 produces a feedback signal that a summation element 504 combines with the filtered signal to further reduce any trailing intersymbol interference. A decision element 506 operates on the output of the summation element 504, the output of FFE filter 502, or the output of CTLE filter 413, comparing the filtered signal to one or more decision thresholds to identify the channel symbol represented that the filtered signal represents.

If present, the FBF 503 derives the feedback signal from the sequence of symbol decisions 507 to correct for trailing intersymbol interference. The illustrated equalization and detection arrangement is known as a decision feedback equalizer (DFE), and it yields a sequence of symbol decisions, which may be supplied to a first-in first-out (FIFO) buffer 417. In the figure, the FIFO buffer contents are provided for output as a receive data (RXD) signal.

The input and output of decision element 506 may be differenced to provide an equalization error signal 512 for use by a controller 514 and a clock recovery module 518. The controller 514 uses the equalization error signal 512 combined with the filtered signal to optimize coefficients of the FFE 502 and FBF 503. The clock recovery module 518 uses the error signal, usually in combination with the symbol decisions 507, to derive the sampling clock signal 516.

FIFO buffer 417 stores the digital data stream bits or symbols for retransmission across the short-reach link to the host. The received data stream may be structured as a sequence of frames each having a header and a payload. One or more fields in the frame headers may contain backchannel information, and if so, the extraction module 508 detects those fields and extracts the backchannel information for local use. As one example, the backchannel information may include adaptation information for the local pre-equalization filter 418.

In addition to optimizing FFE and FBF coefficients, the controller 514 may further determine adjustments for the CTLE filter 413 and for the remote pre-equalization, or “transmit” filter. The controller 514 outputs locally-generated information (LOCAL_INFO), which includes the transmit filter coefficient adjustments and the convergence status. Where the system supports the use of a backchannel, the LOCAL_INFO is supplied to training controller 430 for communicating in the reverse direction on the data lane. Training control module 430 communicates the transmit filter adjustments and the convergence status via the backchannel to the source of the CH_IN signal. In that vein, the received signal includes back-channel information from the source of the CH_IN signal. The extraction module 508 detects the back-channel information (BACK_INFO) and passes it to the training controller 430. Once convergence is achieved, the receive chain is ready for normal operation.

Training controller 430 receives the BACK INFO and LOCAL INFO. During normal operations, a multiplexer supplies the transmit data stream to pre-equalizer 418 with unmodified frame headers, but during the link speed negotiation and equalizer training phases, the multiplexer may introduce modified frame headers into the transmit data stream. During these phases, the transmit data stream comprises a training signal, and the header has fields for the backchannel information including convergence status and transmit filter coefficient adjustments (LOCAL_INFO) received from controller 514. Note that even after the local receiver indicates filter convergence has occurred, the training controller 430 may prolong the training phase to coordinate training phase timing across each link of the channel.

The training controller 430 further accepts any back-channel information (BACK_INFO) extracted by module 508 from received training frames sent by the remote node. The training controller 430 applies the corresponding adjustments to the coefficients of pre-equalizer 418.

Though not expressly shown here, it is expected that the filters may be parallelized, and the receiver augmented with one or more level finders to aid in determining decision thresholds and cumulative probability distributions for signals at upper and lower edges of the equalized signal decision eyes. Implementation and configuration detail for such features can be found in co-owned U.S. App. 16/691,523, filed Nov. 21, 2019 and titled “Multi-function level finder for SerDes”, which is hereby incorporated herein by reference.

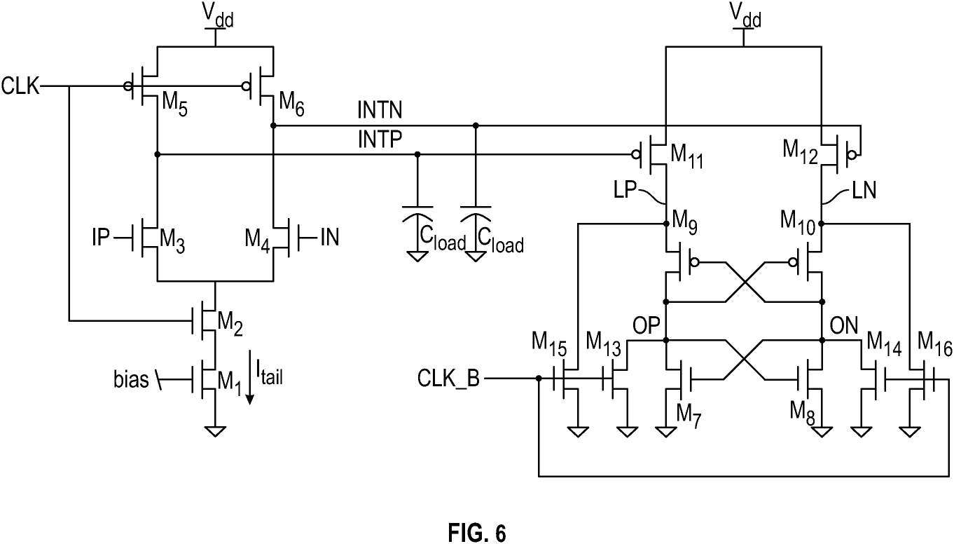

For each decision threshold, decision element 506 includes a clocked voltage comparator such as that shown in FIG. 6. The comparator of FIG. 6 includes a pre-amplifier (transistors M1-M6 and C_{load}) operated by clock signal CLK and a latch (transistors M7-M16) operated by a complementary clock signal /CLK (aka “clock bar” or CLK_B).

When the clock signal CLK is low, the amplifier’s enable transistor M2 disables current flow through differential transistors M3, M4. The low clock signal CLK also turns on pre-charge transistors M5, M6 to pre-charge the load capacitances C_{load}, raising the voltage of integration nodes INTP, INTN to the upper voltage rail V_{dd}. When the load capacitances C_{load} are pre-charged, the latch’s sense transistors M11, M12 are disabled.

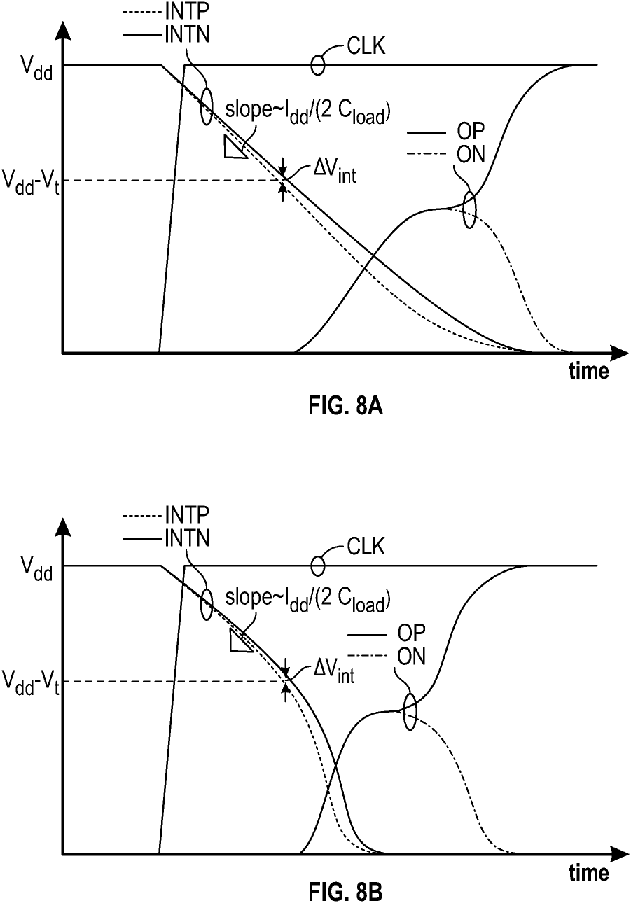

When clock signal CLK is low, the complementary clock signal CLK_B is high, turning on the latch’s reset transistors M13-M16 and thereby discharging the parasitic capacitances of the latch’s intermediate nodes LP, LN, and the latch’s output nodes OP, ON. Referring jointly to FIG. 6 and FIG. 8A, we note that the left side of FIG. 8A represents this reset state (INTP, INTN at Vdd; OP, ON at zero).

When the clock signal CLK transitions to high (and the complementary clock signal CLK_B goes low), the reset transistors M13-M16 are disabled, as are the pre-charge transistors M5, M6. The clock signal CLK turns on enable transistor M2, allowing bias transistor M1 to act as a current sink, drawing current from the shared source node of differential transistor pair M3, M4. The comparator’s inputs, labeled “IP” and “IN”, are supplied to the gates of transistors M3, M4, causing the current sink to preferentially draw current through whichever of the differential transistors M3, M4 receives the higher of the input voltages IP, IN, preferentially discharging the corresponding load capacitance.

FIG. 8A represents the circumstance in which IP is slightly larger than IN, preferentially drawing current from INTP through M3. As INTP and INTN cross the turn on voltage (V_{dd}-Vₜ), the corresponding sense transistors M11, M12, begin charging the corresponding intermediate and output nodes. In the FIG. 8A example, INTP discharges more quickly, causing sense transistor M11 to turn on before sense transistor M12. Thus (after accounting for a capacitive effect causing both output node voltages to increase in tandem) the voltage of intermediate node LP and output node OP begins rising relative to that of the output node ON. The cross-coupled latch transistors M7-M10 operate to drive the output nodes OP, ON to complementary states, providing positive feedback that accelerates the divergence of the two output node voltages. Thus, in FIG. 8A, the voltage of output node OP is driven to the upper voltage rail V_{dd} while the voltage of output node ON is driven to the lower voltage rail (ground), correctly indicating that the IP input node voltage exceeds the IN input node voltage.

The load capacitances C_{load} provide an integration operation to measure the accumulated voltage difference ΔVᵢₙₜ over the time it takes for the INTP, INTN voltages to ramp down to the sense transistor turn on voltage (V_{dd}-Vₜ), thereby filtering any noise on the input signals IP, IN. The pre-amplifier’s thermal and flicker noise can be reduced by increasing the load capacitance; however, the charging and discharging of the load capacitances causes power dissipation that also increases when the load capacitance is increased.

The inventor has observed that only the initial portion of the integration operation (the portion before the INTP, INTN signals reach the turn on voltage of the sense transistors) provides any benefit. After the latch begins its operation, there is no further need for integration. Accordingly, there exists an opportunity for a significant reduction in power consumption with no performance loss (or conversely, an opportunity to significantly enhance performance without a commensurate increase in power consumption) if the integration operation is suitably modified.

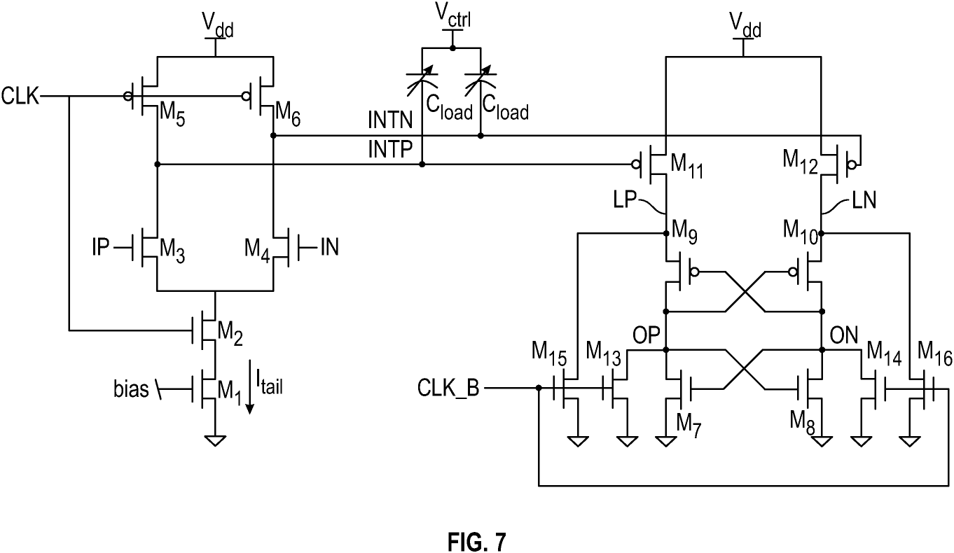

As one example, the clocked voltage comparator may be implemented as shown in FIG. 7, using a varactor rather than the fixed load capacitance of FIG. 6. The term “varactor” is a portmanteau of the phrase “variable capacitor”, and refers to a circuit element having a capacitance that can be varied. Often, though not necessarily, varactors are implemented using the depletion region of a reverse-biased junction between p-type and n-type semiconductors. The “small signal” capacitance of a depletion region is inversely proportional to its thickness, which in turn is approximately proportional to the square root of the reverse bias (after accounting for the junction’s built-in voltage).

This voltage dependence of a varactor can be used to provide a load capacitance that begins at a high value and falls off below the turn on voltage of the sense transistors. In FIG. 7, varactors are coupled between a control voltage V_{ctrl} and the INTP, INTN nodes. The control voltage V_{ctrl} is set near the upper rail voltage to minimize depletion layer thickness (and maximize load capacitance) for the initial portion of the integration operation, while causing the load capacitance to be significantly reduced for the later portions of the integration operation. As shown in FIG. 8B, the slope of the discharge ramps for INTP, INTN are initially comparable to those for the fixed load capacitances (FIG. 8A), but increase significantly in later portions of the integration operation where the decreased capacitance requires less discharge current.

Numerous alternative forms, equivalents, and modifications will become apparent to those skilled in the art once the above disclosure is fully appreciated. For example, variable capacitances can be provided with other mechanisms, potentially including switched arrangements that isolate some or all of the load capacitance from further discharging once the latch begins to operate. Further, disclosure shows a CMOS implementation of the clocked voltage comparator circuit, but those familiar with the art will recognize how the disclosed principles can be used with other semiconductor and switching technologies including NMOS, PMOS, JFET, and BJT. Moreover, signal polarities are reversible, such that with suitable element substitutions known to those in the art references to pre-charging, discharging, upper voltage rail, lower voltage rail, enable, disable, etc., can be exchanged. Still further, though the preceding disclosure focuses on clocked voltage comparators, clocked comparators and latches of other varieties would also benefit from the use of variable load capacitances. It is intended that the claims be interpreted to embrace all such alternative forms, equivalents, and modifications that are encompassed in the scope of the appended claims.

1. A voltage comparator that comprises:
a latch having two sense transistors to set a latch to either of two complementary states;
two varactors each coupled to enable one of the two sense transistors upon reaching a turn on voltage; and
a differential amplifier to increase a voltage drop across each of the two varactors during an integration phase of a voltage comparison, each of the two varactors providing a capacitance that decreases during the integration phase.

2. The voltage comparator of claim 1, further comprising:
pre-charge transistors to decrease said voltage drops before each voltage comparison.

3. (canceled)

4. The voltage comparator of claim 1, further comprising: reset transistors to reset the latch before each voltage comparison.

5. A voltage comparator comprising:
an amplifier that provides a current based a difference between two input voltages;
at least one varactor having a voltage drop increased by the current; and
at least one pair of cross-coupled transistors that derive a latch state based at least in part on a voltage of the at least one varactor.

6. The voltage comparator of claim 5, further comprising:
a clock-controlled transistor to decrease the voltage drop to a predetermined voltage before each voltage comparison,
wherein for each voltage comparison, the capacitance of the at least one varactor decreases as the voltage drop increases.

7. The voltage comparator of claim 6, further comprising: clock-controlled reset transistors to place the at least one pair of cross-coupled transistors into an unlatched state before each voltage comparison.

8-9. (canceled)

10. A voltage comparison method that comprises:
converting a difference between two input voltages into a current;
applying the current to increase a voltage drop across a varactor; and
deriving a latch state based at least in part on a voltage of the varactor, the latch state indicating which of the two input voltages is greater.

11. The voltage comparison method of claim 10, further comprising:
before each voltage comparison, setting the voltage drop to a predetermined voltage.

12. The voltage comparator method of claim 11, further comprising: resetting the latch state while setting the voltage drop.

13-14. (canceled)

15. A voltage comparison method that comprises:
converting two input voltages into two respective currents;
applying each of the two respective currents to increase a voltage drop across one of two respective varactors; and
deriving a latch state from the varactor voltages, the latch state indicating which of the two input voltages is greater.

16. The voltage comparison method of claim 15, further comprising:
before each voltage comparison, setting the voltage drops to a predetermined voltage.

17. The voltage comparator method of claim 16, further comprising: resetting the latch state while setting the voltage drops.

18-19. (canceled)
